(19) United States
(12) Patent Application Publication
(10) Pub. No.: US 2025/0036175 A1
(43) Pub. Date: Jan. 30, 2025

(54) ELECTRONIC DEVICE INCLUDING HEAT DISSIPATION STRUCTURE

(71) Applicant: Samsung Electronics Co., Ltd., Suwon-si (KR)

(72) Inventors: Jongkil PARK, Suwon-si (KR); Bonghwan KIM, Suwon-si (KR); Joseph AHN, Suwon-si (KR); Hajoong YUN, Suwon-si (KR); Hui JEONG, Suwon-si (KR)

(21) Appl. No.: 18/786,201

(22) Filed: Jul. 26, 2024

Related U.S. Application Data
(63) Continuation of application No. PCT/KR2024/010977, filed on Jul. 26, 2024.

(30) Foreign Application Priority Data
Jul. 26, 2023 (KR) 10-2023-0097792
Aug. 31, 2023 (KR) 10-2023-0115802

(51) Int. Cl. G06F 1/20

(52) U.S. Cl. CPC G06F 1/203; G06F 2200/201

(57) ABSTRACT

According to an embodiment of the disclosure, there may be provided an electronic device comprising: a housing forming an exterior of the electronic device, a printed circuit board on which at least one component is disposed, and a heat dissipation member contacting the at least one component or contacting the at least one component through a thermally conductive material, and including a first plate, a second plate and a wick. The wick may be disposed on a second plate inside the heat dissipation member and include a first portion and a second portion. The first portion may be thicker than the second portion.

### CROSS-REFERENCE TO RELATED APPLICATIONS

This application is a continuation of International Application No. PCT/KR2024/010977 designating the United States, filed on Jul. 26, 2024, in the Korean Intellectual Property Receiving Office and claiming priority to Korean Patent Application Nos. 10-2023-0097792, filed on Jul. 26, 2023, and 10-2023-0115802, filed on Aug. 31, 2023, in the Korean Intellectual Property Office, the disclosures of each of which are incorporated by reference herein in their entireties.

### BACKGROUND

### Field

The disclosure relates to electronic devices, for example, electronic devices including a heat dissipation structure for moving, dispersing and/or dissipating heat generated internally.

### Description of Related Art

Generally, the electronic device may refer to a device performing a particular function according to its equipped program, such as a home appliance, an electronic scheduler, a portable multimedia player, a mobile communication terminal, a tablet PC, a video/sound device, a desktop PC or laptop computer, a navigation for automobile, etc. For example, electronic devices may output stored information as voices or images. As electronic devices are highly integrated and high-speed, high-volume wireless communication becomes commonplace, mobile communication terminals are recently being equipped with various functions. For example, an electronic device comes with the integrated functionality, including an entertainment function, such as playing video games, a multimedia function, such as replaying music/videos, a communication and security function for mobile banking, and a scheduling or e-wallet function.

As the performance of electrical elements equipped with processors or communication modules, such as integrated circuit chips, enhances dramatically, an environment in which these various functions may be integrated into one electronic device is provided. Enhancement in the performance of electrical elements not only provides an environment in which various functions may be mounted on a single electronic device, but also enhance data communication and processing speeds.

The above-described information may be provided as related art for the purpose of helping understanding of the disclosure. No claim or determination is made as to whether any of the foregoing is applicable as background art in relation to the disclosure.

### SUMMARY

According to an example embodiment of the disclosure, there may be provided an electronic device comprising: a housing forming an exterior of the electronic device, a printed circuit board on which at least one component is disposed, and a heat dissipation member contacting the at least one component or contacting the at least one component through a thermally conductive material, and including a first plate, a second plate and a wick. The wick may be disposed on a second plate inside the heat dissipation member and include a first portion and a second portion. The first portion may be thicker than the second portion.

According to an example embodiment of the disclosure, there may be provided an electronic device comprising: a housing including a first surface and a second surface facing in a direction opposite to the first surface, a support accommodated in the housing between the first surface and the second surface, a heat dissipation member disposed on one surface of the support and including a wick, a printed circuit board accommodated in the housing between the first surface and the second surface, and having at least one component disposed thereon, and a thermally conductive material disposed between the at least one component and the heat dissipation member. The wick may include a first portion disposed on a heat receiving portion and a second portion disposed on a heat dissipation portion. Either the first portion or the second portion may further include a reinforced portion as compared with the other.

According to an example embodiment of the disclosure, there may be provided an electronic device comprising: a housing including a first surface and a second surface facing in a direction opposite to the first surface, a support accommodated in the housing between the first surface and the second surface, and a heat dissipation member supported by the support, and including a heat receiving portion including a portion configured to vaporize a working fluid based on heat being absorbed from a heat source disposed in the electronic device, a heat dissipation portion configured to liquify the working fluid based on the heat being discharged, and a wick disposed on the heat receiving portion and the heat dissipation portion. The wick may include a first portion disposed on the heat receiving portion and a second portion disposed on the heat dissipation portion. Either the first portion or the second portion may further include a reinforced portion as compared with the other.

### BRIEF DESCRIPTION OF THE DRAWINGS

The foregoing and other aspects, features, and/or advantages of certain embodiments of the present disclosure will be more apparent from the following detailed description, taken in conjunction with the accompanying drawings, in which:

FIG. 1 is a block diagram illustrating an example electronic device in a network environment according to an embodiment of the disclosure;

FIG. 2 is a front perspective view illustrating an electronic device according to an embodiment of the disclosure;

FIG. 3 is a rear perspective view illustrating the electronic device of FIG. 2 according to an embodiment of the disclosure;

FIG. 4 is an exploded front perspective view illustrating the electronic device of FIG. 2, according to an embodiment of the disclosure;

FIG. 5 is a rear exploded perspective view illustrating the electronic device of FIG. 2 according to an embodiment of the disclosure;

FIG. 6 is a diagram illustrating an example heat dissipation member and a state in which the heat dissipation member is disposed in a housing according to an embodiment of the disclosure;

FIG. 7 is a cross-sectional view illustrating an example heat dissipation structure of an electronic device according to an embodiment of the disclosure;

FIG. 8 is a cross-sectional view illustrating an example heat dissipation member according to an embodiment of the disclosure;

FIG. 9 is a cross-sectional view illustrating an operation principle of a heat dissipation member according to an embodiment of the disclosure;

FIG. 10 is a cross-sectional view illustrating an example heat dissipation structure of an electronic device according to an embodiment of the disclosure;

FIG. 11 is a cross-sectional view illustrating an example heat dissipation member according to an embodiment of the disclosure;

FIG. 12 is a diagram illustrating a an example dissipation member according to an embodiment of the disclosure;

FIG. 13 is a diagram illustrating an example heat dissipation member according to an embodiment of the disclosure;

FIG. 14 is a diagram illustrating a state in which a thermally conductive block is disposed on a rear surface of a heat dissipation member according to an embodiment of the disclosure;

FIG. 15 is a cross-sectional view illustrating a shielding sheet according to an embodiment of the disclosure;

FIG. 16 is a graph illustrating a temperature enhancing effect of a heat dissipation structure according to an embodiment of the disclosure; and

FIGS. 17A and 17B are diagrams illustrating a temperature enhancing effect of an electronic device according to an embodiment of the disclosure.

Throughout the drawings, like reference numerals may be assigned to like parts, components, and/or structures.

### DETAILED DESCRIPTION

Heat generated from electrical element(s), such as integrated circuit chips, may impair the operating environment of electronic devices. As the performance of various electrical elements enhances and the degree of integration of electronic devices increases, and/or the capacity of image or sound data increases, deterioration of the operating environment due to heat generation may increase. Integrated circuit chips equipped with circuit devices, such as processors, may generate more heat than other electrical elements. Further, as development of electronic devices is directed to reducing the thickness, if more heat is generated in a narrower area, and/or the generated heat is accumulated in the electronic device, the operation environment of the electrical component(s) may further worsen. In order to enhance heat dissipation performance of the electronic device, a heat dissipation member (e.g., vapor chamber) that performs cooling using a phase change between liquid and gas may be employed. However, even if the heat dissipation performance of the electronic device is partially enhanced, enhancement for the temperature of the heat source may not be obtained due to the heat resistance between the heat dissipation member and the heat source (e.g., the processor).

Embodiments of the disclosure aim to address the foregoing issues and/or drawbacks and provide advantages described below, by providing an electronic device including a heat dissipation structure for moving, dispersing, and/or dissipating internally generated heat.

Embodiments of the disclosure may provide an electronic device including a heat dissipation member with reduced heat resistance between heat dissipation member and heat source (e.g., a processor).

The disclosure is not limited to the foregoing, and other unmentioned aspects will be apparent to one of ordinary skill in the art from the following description.

The following description taken in conjunction with the accompanying drawings may provide an understanding of various example implementations of the disclosure, including claims and their equivalents. The various example embodiments disclosed in the following description entail various specific details to aid understanding, but are regarded as one of various embodiments. Accordingly, it will be understood by those skilled in the art that various changes and modifications may be made to the various implementations described in the disclosure without departing from the scope and spirit of the disclosure. Further, descriptions of well-known functions and configurations may be omitted for clarity and brevity.

The terms and words used in the following description and claims are not limited to the bibliographical meaning, but may be used to clearly and consistently describe embodiments of the disclosure. Therefore, it will be apparent to those skilled in the art that the following description of various implementations of the disclosure is provided merely for the purpose of description, not for the purpose of limiting the disclosure defined as the scope of the claims and equivalent thereto.

The singular forms “a,” “an,” and “the” are intended to include the plural forms as well, unless the context clearly indicates otherwise. Thus, as an example, “a component surface” may be interpreted as including one or more of the surfaces of a component.

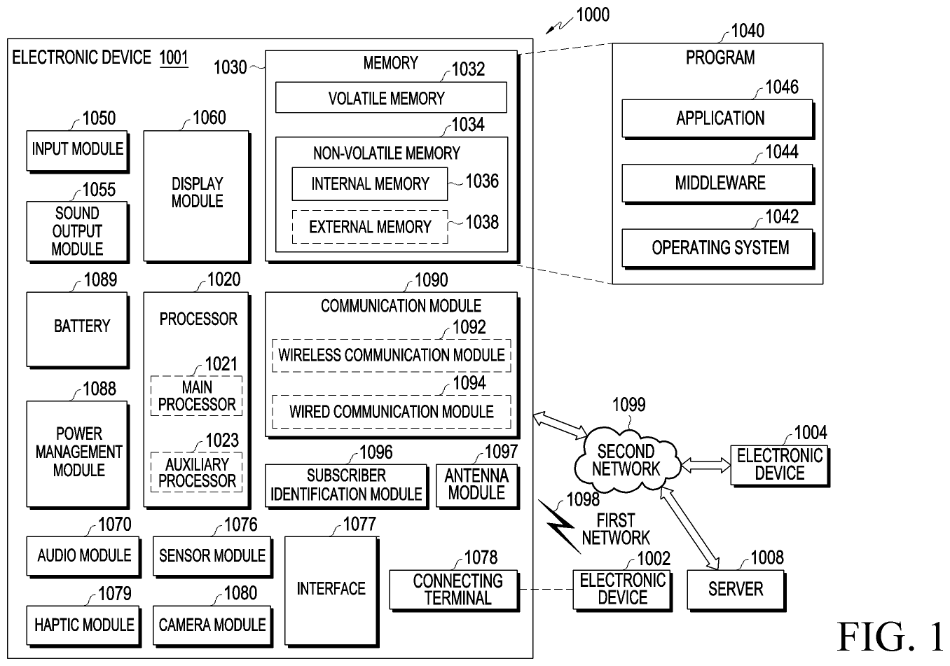

FIG. 1 is a block diagram illustrating an example electronic device 101 in a network environment 100 according to various embodiments. Referring to FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., the electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mm Wave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module may include an antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

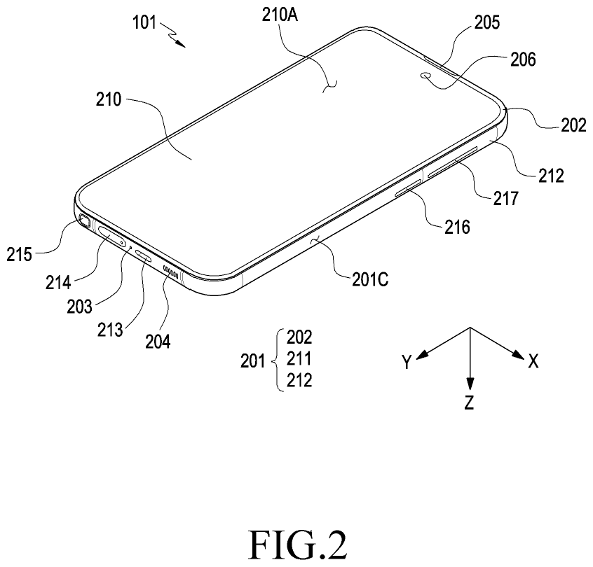

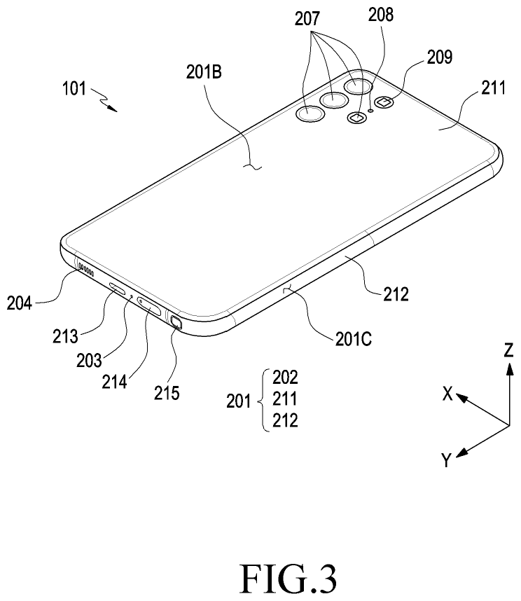

FIG. 2 is a front perspective view illustrating an electronic device 101 according to an embodiment of the disclosure. FIG. 3 is a rear perspective view illustrating an electronic device 101 according to an embodiment of the disclosure.

In the following detailed description, the length direction of the electronic device 101 may be defined as the ‘Y-axis direction’, the width direction as the ‘X-axis direction’, and/or the height direction (the thickness direction) as the ‘Z-axis direction’. In the following detailed description, the mentioned length direction, width direction, and/or height direction (or thickness direction) may indicate the length direction, the width direction, and/or the height direction (or thickness direction) of the electronic device. In an embodiment, ‘negative/positive (−/+)’ may be mentioned together with the Cartesian coordinate system illustrated in the drawings with respect to the direction in which the component is oriented. For example, referring to FIG. 2, the front surface of the electronic device 101 or housing 201 may be defined as a ‘surface facing in the −Z direction,’ and the rear surface may be defined as a ‘surface facing in the +Z direction’. According to an embodiment, the arrangement relationship in the height direction of a component or another component, that is, the reference as to whether a component is on/under another component, may follow the +Z-axis direction/−Z-axis direction. In other words, when a component is disposed on another component, it may refer, for example, to the component being disposed on the −Z-axis direction with respect to the other component, and when a component is disposed under another component, it may refer, for example, to the component being disposed on the −Z-axis direction with respect to the other component. It should be noted that although a component is disposed on or under another component, it does not necessarily refer to the entire component being disposed on or under the entire other component. For example, it should be noted that a portion of the component may be disposed on a portion of the other component while another portion of the component may be disposed under another portion of the other component. According to an embodiment, when a component is viewed from thereabove, it may refer, for example, to the component being viewed from the −Z-axis direction to the +Z-axis direction from a place a predetermined distance away from the component. According to an embodiment, when a component faces in a certain direction, it may be understood as including when the component faces in a direction parallel to the certain direction as well as when the component faces in the same direction as the certain direction. In the following description, it should be noted that when a component overlaps (or is stacked on) another component, the above description of the arrangement relationship in height direction may apply. In describing the direction, when ‘negative/positive (−/+)’ is not described, it may be interpreted as including both the + direction and the −direction unless separately defined. For example, the ‘Z-axis direction’ may be interpreted as including both the +Z direction and the −Z direction. Likewise, ‘X-axis direction’ may be interpreted as including both+X direction and −X direction, and ‘Y-axis direction’ may be interpreted as including both+Y direction and −Y direction. In describing directions, facing in any one axis among the three axes of the orthogonal coordinate system may include facing in a direction parallel to the axis. Hereinafter, in the following description, ‘first direction’ may refer, for example, to the Z-axis direction or a direction parallel to the Z axis, and ‘second direction’ may refer, for example, to the X-axis direction or a direction parallel to the X axis. Further, ‘third direction’ may refer, for example, to the Y-axis direction or a direction parallel to the Y axis. It should be noted that the directions are so defined with respect to the Cartesian coordinate system shown in the drawings for the sake of brevity of description, and the description of these directions or components do not limit various embodiments of the disclosure.

Referring to FIGS. 2 and 3, according to an embodiment, an electronic device 101 may include a housing 201 with a front surface 201A, a rear surface 201B, and a side surface 201C surrounding a space between the front surface 201A and the rear surface 201B. In an embodiment (not shown), the housing 201 may denote a structure forming part of the front surface 201A, the rear surface 201B, and the side surface 201C of FIG. 2. According to an embodiment, at least part of the front surface 201A may have a substantially transparent front plate 202 (e.g., a glass plate or polymer plate including various coat layers). The rear surface 201B may be formed by a rear plate 211. The rear plate 211 may be formed of, e.g., glass, ceramic, polymer, metal (e.g., aluminum, stainless steel (STS), or magnesium), or a combination of at least two thereof. The side surface 201C may be formed by a side bezel structure (or a “side member”) 212 that couples to the front plate 202 and the rear plate 211 and includes a metal and/or polymer. In an embodiment, the front plate 202 and side bezel structure 212 may be formed as one body and may include the same material. The rear plate 211 and the side bezel plate 212 may be integrally formed together and include the same material (e.g., glass, metal, such as aluminum, or ceramic). According to an embodiment, the front surface 201A and/or the front plate 202 may be interpreted as a part of the display 210. According to an embodiment, the housing 201 may include a front plate 202 and a rear plate 211.

According to an embodiment, the electronic device 101 may include at least one of a display 210, audio modules 203, 204, and 205 (e.g., the audio module 170 of FIG. 1), a sensor module (e.g., the sensor module of FIG. 1). 176), camera modules 206 and 207 (e.g., the camera module 180 of FIG. 1), a key input device 216 or 217 (e.g., the input module 150 of FIG. 1), and connector holes 213 and 214 (e.g., the connection terminal 178 of FIG. 1). According to an embodiment, the electronic device 101 may exclude at least one (e.g., the connector hole 214) of the components or may add other components.

According to an embodiment, the display 210 may be visually revealed through, e.g., a majority portion of the front plate 202. In an embodiment, at least a portion of the display 210 may be visible through the front plate 202 forming the front surface 202A. According to an embodiment, the display 210 may be a flexible display or a foldable display.

According to an embodiment, the surface (or the front plate 202) of the housing 201 may include a screen display area formed as the display 210 is visually exposed. For example, the screen display area may include the front surface 201A.

In an embodiment (not shown), the electronic device 101 may include a recess or opening formed in a portion of the screen display area (e.g., the front surface 201A) of the display 210 and may include at least one or more of an audio module 205, a sensor module (not shown), a light emitting device (not shown), and a camera module 206 aligned with the recess or opening. In an embodiment (not shown), at least one or more of the audio module 205, sensor module (not shown), camera module 206, fingerprint sensor (not shown), and light emitting device (not shown) may be included on the rear surface of the screen display area of the display 210.

In an embodiment (not shown), the display 210 may be disposed to be coupled with, or adjacent, a touch detecting circuit, a pressure sensor capable of measuring the strength (pressure) of touches, and/or a digitizer for detecting a magnetic field-type stylus pen 215.

In various embodiments, at least a portion of the key input device 216 or 217 may be disposed on the side bezel structure 212.

According to an embodiment, the audio modules 203, 204, and 205 may include, e.g., a microphone hole 203 and speaker holes 204 and 205. A microphone for acquiring external sounds may be disposed in the microphone hole 203. In various embodiments, a plurality of microphones may be disposed to detect the direction of the sound. The speaker holes 204 and 205 may include an external speaker hole 204 and a phone receiver hole 205. In an embodiment, the speaker holes 204 and 205 and the microphone hole 203 may be implemented as a single hole, or speakers may be included without the speaker holes 204 and 205 (e.g., piezo speakers). The audio modules 203, 204, and 205 are not limited to the above-described structure. Depending on the structure of the electronic device 101, various design changes may be made—e.g., only some of the audio modules may be mounted, or a new audio module may be added.

According to an embodiment, the sensor modules (not shown) may generate an electrical signal or data value corresponding to an internal operating state or external environmental state of the electronic device 101. The sensor modules (not shown) may include a first sensor module (not shown) (e.g., a proximity sensor) and/or a second sensor module (not shown) (e.g., a fingerprint sensor) disposed on the front surface 201A of the housing 201 and/or a third sensor module (not shown) (e.g., a heart rate monitor (HRM) sensor) and/or a fourth sensor module (not shown) (e.g., a fingerprint sensor) disposed on the rear surface 201B of the housing 201. In an embodiment (not shown), the fingerprint sensor may be disposed on the rear surface 201B as well as on the front surface 201A (e.g., the display 210) of the housing 201. The electronic device 101 may further include sensor modules not shown, e.g., at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor (not shown). The sensor module (not shown) is not limited to the above-described structure. Depending on the structure of the electronic device 101, various design changes may be made—e.g., only some of the sensor modules may be mounted, or a new sensor module may be added.

According to an embodiment, the camera modules 206 and 207 may include a front camera module 206 disposed on the first surface 201A of the electronic device 101 and a rear camera module 207, a flash 208, and/or an IR sensor 209 disposed on the rear surface 201B. The camera modules 206 and 207 may include one or more lenses, an image sensor, and/or an image signal processor. The flash 208 may include, e.g., a light emitting diode (LED) or a xenon lamp. The camera modules 206 and 207 are not limited to the above-described structure. Depending on the structure of the electronic device 101, various design changes may be made—e.g., only some of the camera modules may be mounted, or a new camera module may be added.

According to an embodiment, the electronic device 101 may include a plurality of camera modules (e.g., a dual camera or triple camera) having different attributes (e.g., angle of view) or functions. For example, the rear camera module 207 may include a plurality of camera modules including lenses with different fields of view. For example, the plurality of camera modules may include at least one of a wide-angle camera, an ultra wide-angle camera, a telephoto camera, and an infrared (IR) camera (e.g., a time of flight (TOF) camera, a structured light camera). Further, for example, the plurality of camera modules may include optical zoom cameras with adjustable magnification. According to an embodiment, the electronic device 101 may be configured to operate a designated camera module or another camera module, based on the user's selection, or under a predetermined environment, for the plurality of camera modules. According to an embodiment, the IR camera may be operated as at least a portion of the sensor module. For example, the TOF camera may be operated as at least a portion of a sensor module (not shown) for detecting the distance to the subject.

According to an embodiment, the camera modules 206 and 207 may include a vertical camera module and/or a folded camera module. The vertical camera module may be a module including a camera where the path along which the light incident on the lens assembly reaches the image sensor is formed in a straight line, rather than being bent. In the vertical camera module, during an auto focus (AF) operation or an optical image stabilization (OIS) operation, a relative motion between the lens barrel and the camera housing surrounding the lens barrel may be performed (or a relative motion between the image sensor and the camera housing). Further, the vertical camera module may also include a camera module in which the lens barrel and the camera housing are not relatively moved, but fixed in position, e.g., with fixed focus. The folded camera module may refer, for example, to a camera module in which when the light incident on the lens assembly reaches the image sensor, the path is bent at least once and may typically include a member (e.g., a prism or a mirror) to reflect or refract light at least once. Here, whether the path in which light reaches the image sensor is bent may be not based on bending the light by each lens included in the lens assembly but based on bending the light by the member (e.g., a prism or a mirror). According to an embodiment, a portion (e.g., front camera) of the camera modules 206 and 207 may include a vertical camera module, and another portion (e.g., rear camera) may include a folded camera module.

According to an embodiment, a portion (e.g., front camera module 206) of the camera modules 206 and 207 may be implemented as an under display camera (UDC).

According to an embodiment, the key input device 216 or 217 may be disposed on the side surface 201C of the housing 201. In an embodiment, the electronic device 101 may exclude all or some of the above-mentioned key input devices 216 and 217 and the excluded key input devices 216 and 217 may be implemented in other forms, e.g., as soft keys, on the display 210. In an embodiment, the key input device 216 or 217 may include a sensor module (not shown) disposed on the rear surface 201B of the housing 201.

According to an embodiment, the light emitting device may be disposed on, e.g., the front surface 201A of the housing 201. The light emitting device (not illustrated) may provide, e.g., information about the state of the electronic device 101 in the form of light. In an embodiment, the light emitting device (not shown) may provide a light source that interacts with, e.g., the front camera module 206. The light emitting device (not shown) may include, e.g., a light emitting diode (LED), an infrared (IR) LED, and/or a xenon lamp.

According to an embodiment, the connector holes 213 and 214 may include a first connector hole 213 for receiving a connector (e.g., an earphone jack) for transmitting/receiving audio signals to/from an external electronic device or a connector (e.g., a USB connector) for transmitting/receiving power and/or data to/from the external electronic device and/or a second connector hole 214 for receiving a storage device (e.g., a subscriber identification module (SIM) card, a secure digital (SD) memory card). According to an embodiment, the first connector hole 213 and/or the second connector hole 214 may be omitted. The connector holes 213 and 214 are not limited to the above-described structure. Depending on the structure of the electronic device 101, various design changes may be made, such as mounting only some of the connector holes or adding a new connector hole.

The pen input device 215 (e.g., a stylus pen) may be guided and detachably inserted through a hole formed in a side surface of the housing 201 into the inside of the housing 201. The pen input device 120 may include a button for easy detachment. A separate resonant circuit may be embedded in the pen input device 215 and may interwork with an electromagnetic induction panel (e.g., a digitizer) included in the electronic device 101. The pen input device 215 may come in, e.g., an electro-magnetic resonance (EMR), active electrical stylus (AES), or electric coupled resonance (ECR) scheme.

The electronic device 101 disclosed in FIGS. 2 and 3 has a bar-type or plate-type appearance but the disclosure is not limited thereto. For example, the illustrated electronic device may be part of a rollable electronic device or a foldable electronic device. “Rollable electronic device” may refer, for example, to an electronic device at least a portion of which may be wound or rolled or accommodated in the housing 201 as the display may be bent and deformed. As the display is stretched out or is visible to the outside in a larger area according to the user's need, the rollable electronic device may use an expanded second display area. “Foldable electronic device” may refer, for example, to an electronic device that may be folded in directions to face two different areas of the display or in directions opposite to each other. In general, in the portable state, the foldable electronic device may be folded so that the two different areas of the display face each other and, in an actual use state, the user may unfold the display so that the two different areas form a substantially flat shape. In various embodiments, the electronic device 101 according to various embodiments of the disclosure may be interpreted as including various electronic devices, such as a laptop computer or a home appliance, as well as a portable electronic device, such as a smart phone.

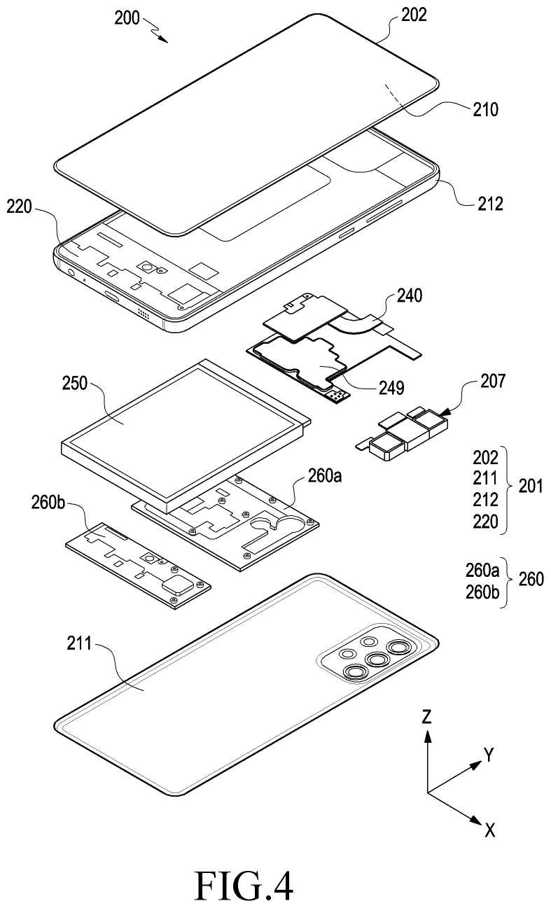

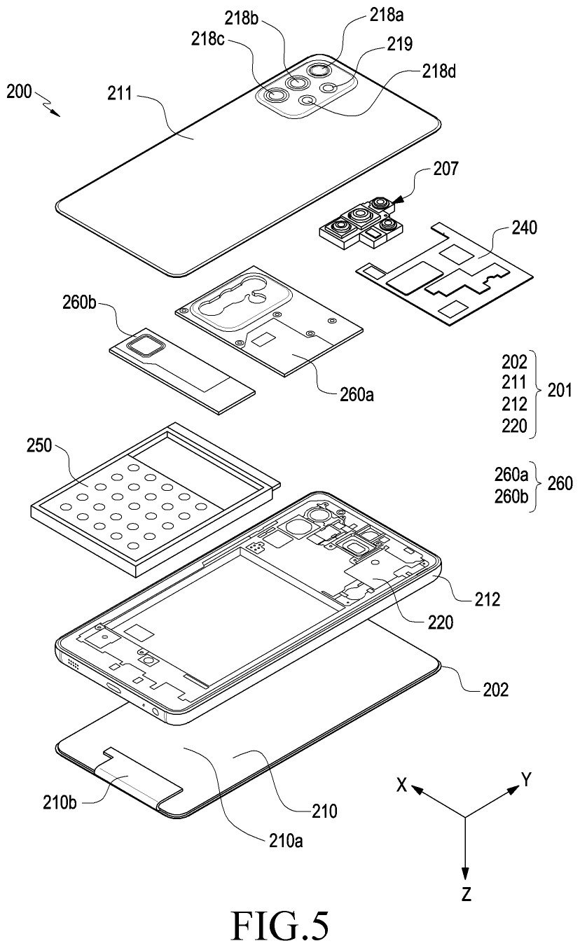

FIG. 4 is an exploded front perspective view illustrating the electronic device of FIG. 2, according to an embodiment of the disclosure. FIG. 5 is a rear exploded perspective view illustrating the electronic device of FIG. 2 according to an embodiment of the disclosure.

Referring to FIGS. 4 and 5, an electronic device 101 (e.g., the electronic device 101 of FIG. 1, 2 or 3) may include a side bezel structure 212, a first support member 220 (e.g., a bracket), a front plate 202, a display 210, a printed circuit board (or a substrate assembly) 240, a battery 250, a second support member 260 (e.g., a rear case), an antenna, a camera module 207, and a rear plate 211. In an embodiment, the electronic device 200 may exclude at least one (e.g., the first support member 220 or the second support member 260) of the components or may add other components. At least one of the components of the electronic device 200 may be the same or similar to at least one of the components of the electronic device 101 of FIG. 2 or 3 and no duplicate description is made below.

The first support member 220 may be disposed inside the electronic device 200 to be connected with the side bezel structure 212 or integrated with the side bezel structure 212. The first support member 220 may be formed of, e.g., a metallic material and/or non-metallic material (e.g., polymer). When at least partially formed of a metallic material, a portion of the side bezel structure 212 or the first support member 220 may function as an antenna. The display 210 may be joined onto one surface of the first support member 220, and the printed circuit board 240 may be joined onto the opposite surface of the first support member 232. A processor (e.g., the processor 120 of FIG. 1), memory (e.g., the memory 130 of FIG. 1), and/or an interface (e.g., the interface 177 of FIG. 1) may be mounted on the printed circuit board 240. The processor may include one or more of, e.g., a central processing unit, an application processor, a graphic processing device, an image signal processing, a sensor hub processor, or a communication processor. In an embodiment, processor and/or memory may refer to one of the circuit devices mounted in an integrated circuit chip.

According to an embodiment, the first support member 220 and the side bezel structure 212 may be collectively referred to as a housing 201 (or front case). According to an embodiment, the housing 201 may be generally understood as a structure for receiving, protecting, or disposing the printed circuit board 240 or the battery 250. In an embodiment, it may be understood that the housing 201 includes a structure visually or tactilely recognizable by the user on the exterior of the electronic device 200, e.g., the side bezel structure 212, the front plate 202, and/or the rear plate 211. In an embodiment, the ‘front or rear surface of the housing 201’ may refer to the first surface 201A of FIG. 2 or the second surface 201B of FIG. 3. In an embodiment, the first support member 220 may be disposed between the front plate 202 (e.g., the first surface 201A of FIG. 2) and the rear plate 211 (e.g., the second surface 201B of FIG. 3) and may function as a structure for placing an electrical/electronic component, such as the printed circuit board 240 or the camera assembly 207.

The display 210 may include a display panel and a flexible printed circuit board extending from the display panel. It may be understood that the flexible printed circuit board is, e.g., electrically connected to the display panel while at least partially disposed on the rear surface of the display panel. In an embodiment, display may include a protective sheet. In an embodiment, the protective sheet may function as a cushioning structure that absorbs external force (e.g., a low-density elastic material, such as a sponge) or an electromagnetic shielding structure (e.g., a copper sheet (CU sheet)).

According to an embodiment, the display 210 may be disposed on the inner surface of the front plate 202 and, by including a light emitting layer, output a screen through at least a portion of the front plate 202 or the first surface 201A of FIG. 2. As mentioned above, the display 210 may output substantially the entire area of the front plate 202 or the first surface 201A of FIG. 2.

The memory may include, e.g., a volatile or non-volatile memory.

The interface may include, e.g., a high definition multimedia interface (HDMI), a universal serial bus (USB) interface, a secure digital (SD) card interface, and/or an audio interface. The interface may electrically or physically connect, e.g., the electronic device 200 with an external electronic device and may include a USB connector, an SD card/multimedia card (MMC) connector, or an audio connector.

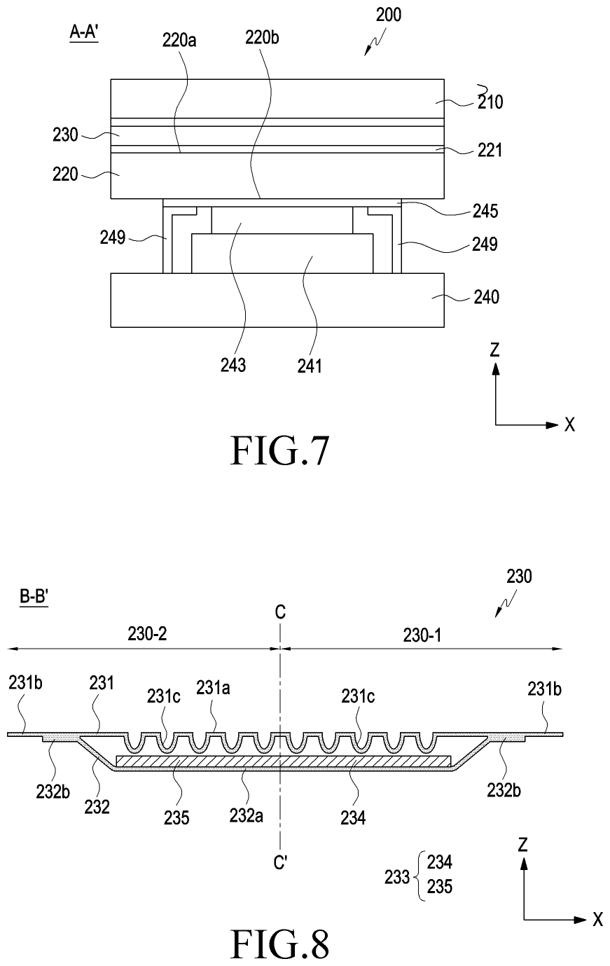

The second support member 260 may include, e.g., an upper support member 260a and a lower support member 260b. In an embodiment, the upper support member 260a, together with a portion of the first support member 220, may be disposed to surround the printed circuit board 240. For example, the printed circuit board 240 may be substantially disposed between the first support member 220 and the second support member 260 (e.g., upper support member 260a). A circuit device (e.g., a processor, a communication module, or memory) implemented in the form of an integrated circuit chip or various electrical/electronic components may be disposed on the printed circuit board 240. According to an embodiment, the printed circuit board 240 may receive an electromagnetic shielding environment from the upper support member 260a. In an embodiment, a shield can 249 (hereinafter the shield can 249 of FIG. 7, which is described below) may be disposed on the printed circuit board 240. For example, the shield can 249 may provide an electromagnetic shielding environment to some areas or spaces on the printed circuit board 240. In an embodiment, the shield can 249 may be disposed to surround at least a portion of at least one component (e.g., an integrated circuit chip equipped with a processor, memory, and/or a communication module).

According to an embodiment, the lower support member 260b may be utilized as a structure in which electrical/electronic components, such as a speaker module and an interface (e.g., a USB connector, an SD card/MMC connector, or an audio connector) may be disposed. In an embodiment, electrical/electronic components, such as a speaker module and an interface (e.g., a USB connector, an SD card/MMC connector, or an audio connector) may be disposed on an additional printed circuit board (not shown). For example, the lower support member 260b, together with the other part of the first support member 220, may be disposed to surround the additional printed circuit board. A speaker module or interface disposed on an additional printed circuit board (not shown) or lower support member 260b may be disposed corresponding to the connector hole (e.g., the first connector hole 213 or the second connector hole 214) or the audio module (e.g., the microphone hole 203 or the speaker hole (e.g., the external speaker hole 204 or the phone receiver hole 205)) of FIG. 2.

The battery 250 may be a device for supplying power to at least one component of the electronic device 200. The battery 450 may include, e.g., a primary cell which is not rechargeable, a secondary cell which is rechargeable, or a fuel cell. At least a portion of the battery 250 may be disposed on substantially the same plane as the printed circuit board 240. The battery 250 may be integrally or detachably disposed inside the electronic device 200.

Although not shown, the antenna may include a conductor pattern implemented on the surface of the first support member 220 and/or the surface of the second support member 260 through, e.g., laser direct structuring (LDS). In an embodiment, the antenna may include a printed circuit pattern formed on the surface of the thin film. The thin film-type antenna may be disposed between the rear plate 211 and the battery 250. The antenna may include, e.g., a near-field communication (NFC) antenna, a wireless charging antenna, and/or a magnetic secure transmission (MST) antenna. The antenna may perform short-range communication with, e.g., an external device or may wirelessly transmit or receive power necessary for charging. In an embodiment, another antenna structure may be formed by a portion or combination of the side bezel structure 212 and/or the first support member 220.

The camera assembly 207 may include at least one camera module. Inside the electronic device 200, the camera assembly 207 may receive at least a portion of the light incident through the optical hole or the camera windows 218a, 218b, 218c, 218d, and 219. In an embodiment, the camera assembly 207 may be disposed on the first support member 220 in a position adjacent to the printed circuit board 240. In an embodiment, the camera module(s) of the camera assembly 207 may be generally aligned with either one of the camera windows 218a, 218b, 218c, 218d, and 219 and be a least partially surrounded by the second support member 260 (e.g., the upper support member 260a).

The following example embodiments may be described with reference to the above-described configurations of the electronic devices 101 and 200. Even when not directly mentioned, the above-described configurations of the various embodiments may likewise apply to the following embodiments. It is noted that the orthogonal coordinate system referred to in the foregoing and/or following embodiments is illustrated for brevity of description, and the various embodiment(s) of the disclosure are not limited thereto. For example, the orthogonal coordinate system mentioned in the disclosure may be differently defined depending on the type (e.g., bar type, foldable type, rollable type, and/or slidable type) of the electronic device to be actually manufactured, the user's use habit, and/or the orientation of the electronic device. In the illustrated embodiment, X-axis direction may refer to the width direction of the electronic device, and Y-axis direction may refer to the length direction of the electronic device. And/or Z-axis direction may refer to the thickness direction of the electronic device. In an embodiment described below, when an integrated circuit chip generates heat, the heat may move to the heat dissipation member through a thermal conductive material, and the direction of heat movement may be understood to be substantially parallel to the Z-axis direction.

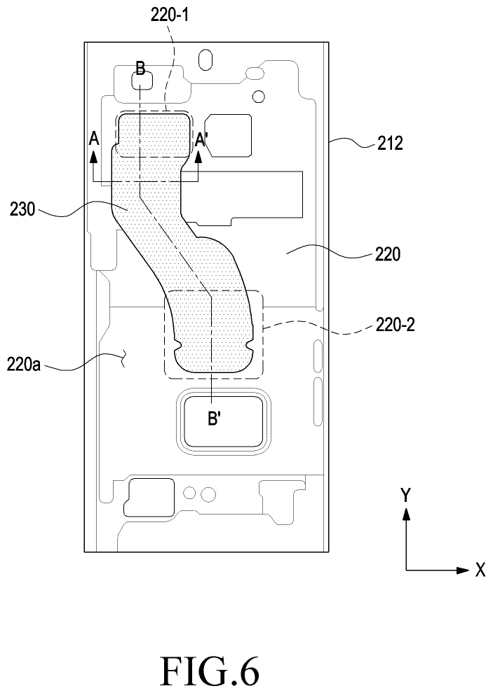

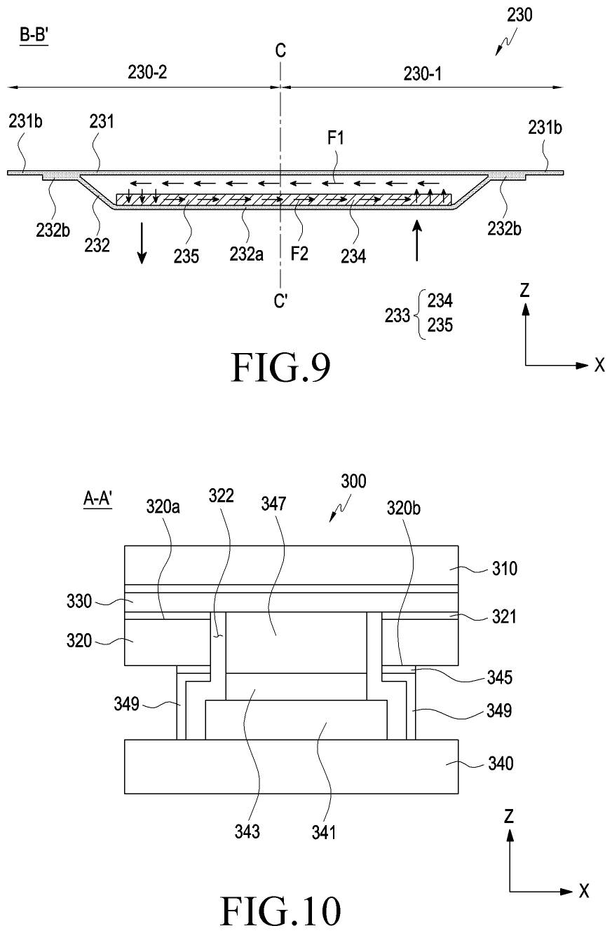

FIG. 6 is a diagram illustrating an example heat dissipation member and a state in which the heat dissipation member is disposed in a housing according to an embodiment of the disclosure. FIG. 7 is a cross-sectional view illustrating an example heat dissipation structure of an electronic device according to an embodiment of the disclosure. FIG. 8 is a cross-sectional view illustrating an example heat dissipation member according to an embodiment of the disclosure. FIG. 9 is a cross-sectional view illustrating an operation principle of example heat dissipation member according to an embodiment of the disclosure.

FIG. 7 may be a cross-sectional view illustrating a heat dissipation structure of an electronic device 200, taken along line A-A′ of FIG. 6 according to an embodiment of the disclosure. FIGS. 8 and 9 may be cross-sectional views illustrating an example heat dissipation member, taken along line B-B′ of FIG. 6 according to an embodiment of the disclosure.

Referring to FIGS. 6 and 7, in the electronic device 200, the heat dissipation structure may be formed between the display 210 and the printed circuit board 240. According to an embodiment, the first support member 220 may be provided as a part of the heat dissipation structure. Since the second support member 260 is not mentioned in the following description of FIG. 6, the first support member 220 may be simply referred to as a “support member 220”. For example, the electronic device 200 and/or the heat dissipation structure may include a support member 220 provided in the housing (e.g., the housing 201 of FIGS. 2 to 5) and a heat dissipation member 230 supported by the support member 220. The heat dissipation member 230 may refer to a component for dissipating heat accumulated in a high-temperature area inside the electronic device to a low-temperature area through a state change and circulation of a working fluid, and may include, e.g., a vapor chamber or a heat pipe. According to an embodiment, due to various electronic components disposed on the support member 220, the support member 220 may include a high-temperature area 220-1 and a low-temperature area 220-2, and the heat dissipation member 230 may refer to a component for dissipating heat of the high-temperature area 220-1 on the support member 220 to the low-temperature area 220-2. In FIG. 6, the high-temperature area 220-1 and the low-temperature area 220-2 are illustrated with dashed lines of a specific size, but it should be noted that this is merely an example. Referring to FIG. 7, it is illustrated that the heat dissipation structure of the disclosure is disposed between the display 210 and the printed circuit board 240, but the position of the heat dissipation structure may not necessarily be limited thereto. For example, the heat dissipation structure may be disposed between the printed circuit board 240 and the rear plate (e.g., the rear plate 211 of FIG. 3). Various embodiments are also possible. An extension of this embodiment may be applied not only to FIG. 7 but also to various embodiments of the disclosure.

According to an embodiment, the support member 220 (e.g., the first support member 220 of FIG. 4 or FIG. 5) may have a substantially flat plate shape, and may be at least partially disposed in a space between the first surface (or front surface) 201A of FIG. 2 or the second surface (or rear surface) 201B of FIG. 3. In an embodiment, the support member 220 may include a first surface 220a facing the display 210 and a second surface 220b facing the printed circuit board 240. According to an embodiment, the heat dissipation member 230 may be fixed on the first surface 220a of the support member 220 by a bonding member 221 such as a double-sided tape. In an embodiment, the heat dissipation member 230 may be fixed to the support member 220 by welding. At least one component 241 may be disposed on the second surface 220b of the support member 220. The at least one component 241 may be disposed on the second surface 220b of the support member 220 while being disposed on one side surface of the printed circuit board 240. Some of the at least one component are heat sources that generates heat, and may be, e.g., at least one chip disposed on at least one side surface of the printed circuit board 240. The at least one chip may include at least one of a power management integrated circuit (PMIC), a power amplifier (PAM), an application processor (AP), a communication processor (CP), a charger integrated circuit (IC), or a DC converter. Hereinafter, an integrated circuit chip as the at least one component 241 is described as an example.

The first surface 220a of the support member 220 may be, e.g., a surface facing the display 210, and the heat dissipation member 230 may be disposed on the first surface 220a. The second surface 220b of the support member 220 is, e.g., a surface facing the rear plate 211, and the printed circuit board 240 may be disposed on the second surface 220b of the support member 220. FIG. 6 illustrates that the support member 220 is stacked on the printed circuit board 240, and the heat dissipation member 230 is disposed on the first surface 220a of the support member 220.

According to an embodiment, the heat dissipation member 230 may absorb heat from at least one component 241 (e.g., an integrated circuit chip) disposed on the printed circuit board 240 and may move or disperse the heat to a wider area. According to an embodiment, the at least one component 241 may be disposed inside the shield can 249, thereby providing an electromagnetically isolated environment. Since the shield can 249 surrounds at least a portion of the at least one component 241, the shield can 249 may serve to shield electromagnetic waves generated from the at least one component 241. In an embodiment, as the shield can 249 is disposed on the heat transfer path to the heat dissipation member 230 as the at least one component 241, the heat transfer efficiency may be reduced.

In an embodiment, the electronic device 200 and/or the heat dissipation structure may include a thermally conductive material (or a thermal interface material (TIM)) 243. For example, it may further include a thermally conductive material 243 protruding to the outside of the at least one component 241 while contacting the at least one component 241. The thermally conductive material 243 is, e.g., a contact type thermally conductive material and may be manufactured by coating or plating a nanofoam with a heat dissipation paint. The material of the heat dissipation paint may include a high thermally conductive material, such as, e.g., graphite, carbon nanotubes, natural recycled materials, silicone, silicon, or graphite. The thermal conductive material 243 may include at least one of, e.g., carbon fiber thermal interface material (TIM), liquid phase thermal interface material (TIM), acrylic thermal interface material (TIM), and/or solid phase thermal interface material (TIM). The thermally conductive material 243 may be configured to transfer heat between the at least one component 241 and the heat dissipation member 230 by contacting another structure, e.g., the shielding sheet 245, inside the shield can 249.

The shielding sheet 245 may be stacked on at least a portion of the shield can 249. According to an embodiment, the shielding sheet 245 may provide a function of shielding electromagnetic waves that may be generated by the at least one component 241. The shielding sheet 245 may be provided for securing electromagnetic shielding performance, e.g., when the shield can 249 is partially opened in a structure in which the thermal conductive material 243 is disposed. According to an embodiment, the shielding sheet 245 may be pre-formed to cover components having different heights and/or the shield can 249, and may provide a structure including an inclined surface or a curved surface through the pre-forming. As another example, the shielding sheet 245 may provide a three-dimensional shape (e.g., a conformal type) structure to encapsulate components of various sizes and shapes disposed on the printed circuit board 240 into one sheet of self-adhesive vinyl, thereby providing a shielding function. According to an embodiment, the shielding sheet 245 may include a shielding film. According to an embodiment, the shielding sheet 245 may be a sheet formed of a metallic material such as copper (Cu), with an adhesive attached thereto. According to an embodiment, the shielding film may be formed of a fiber film having a nanostructure to shield electromagnetic waves. The fiber film may be formed to be thin and long by processing the fibers based on an electrospinning method, and the fibers thus formed may be plated with copper (Cu), then with nickel (Ni), and finally again with copper (Cu). In addition to the shielding function, the shielding sheet 245 may provide a heat transfer function for transferring heat that may be generated by the at least one component 241 to the outside of the at least one component 241. According to an embodiment, the shielding sheet 245 may include a conductive adhesive film. According to an embodiment, the shielding sheet 245 may be formed by stacking a plurality of layers.

According to an embodiment, heat generated from the at least one component 241 may be transferred to another portion (e.g., the support member 220) through an opening of the shield can 249 and/or the thermally conductive material 243 positioned on the opening and the shielding sheet 245. The heat transferred to the support member 220 may be transferred to the low-temperature area inside the electronic device 200 through the heat dissipation member 230.

Referring to FIG. 8, the heat dissipation member 230 may include a first plate 231 (e.g., an upper plate) and a second plate 232 (e.g., a lower plate). When the first plate 231 and the second plate 232 are coupled to each other, a chamber through which the working fluid may flow may be formed therein. For example, the heat dissipation member 230 may include a chamber portion 231a and 232a and a flange portion 231b and 232b provided at at least a portion of an edge of the chamber portion 231a and 232a. According to an embodiment, as the flange portion 231b and 232b is welded onto the support member 220, the heat dissipation member 230 may be stably fixed to the support member 220.

The heat dissipation member 230 may include a wick (or wick structure) 233 and a plurality of fillers 231c disposed inside the chamber. The plurality of fillers 231c may serve to guide the working fluid by at least partially partitioning the space of the chamber inside the heat dissipation member 230 while increasing the durability of the heat dissipation member 230. The wick 233 may be a component such as a metal mesh, a metal microfiber, or a sintered metal powder, and may be configured so that the liquid working fluid may flow inside the wick due to the capillary phenomenon. FIG. 8 illustrates that the plurality of fillers 231c are formed on the first plate 231 and the wick 233 is formed on the second plate 232, but this is merely an example, and other forms may also be applied. According to an embodiment, the wick 233 may be disposed on the second plate 232 inside the heat dissipation member. Here, when the wick 233 is disposed on the second plate 232, it may refer, for example, to the wick 233 being further disposed on the second plate 232 than the first plate 231. When the wick 233 is disposed on the second plate 232, it may refer, for example, to a portion of the wick 233 contacting the inner surface of the second plate 232.

Referring to FIGS. 8 and 9, the heat dissipation member 230 may include a heat receiving portion 230-1, which is a portion where the working fluid is vaporized when heat is absorbed from the heat source disposed in the electronic device 200, and a heat dissipation portion 230-2, which is a portion where the working fluid is liquefied while heat is discharged. According to an embodiment, the wick 233 may be disposed over the heat dissipation part 230-2 and the heat receiving part 230-1. For example, the wick 233 may include a first portion 234 disposed in the heat receiving portion 230-1 and a second portion 235 disposed in the heat dissipation portion 230-2. FIGS. 8 and 9 illustrate that the heat dissipation member 230 is divided into the heat receiving portion 230-1 and the heat dissipation portion 230-2 with respect to a virtual line C-C′. The heat dissipation member 230 may absorb heat throughout the heat receiving portion 230-1 divided with respect to the line C-C′, but is not necessarily limited thereto, and may absorb heat at a specific point. Further, the heat dissipation member 230 may dissipate heat throughout the heat dissipation portion 230-2 divided with respect to the line C-C′, but is not necessarily limited thereto, and may dissipate heat at a specific point.

Referring to FIG. 9, when heat is generated in the heat receiving portion 230-1, the working fluid may be vaporized, and the vaporized working fluid F1 may be moved to the heat dissipation portion 230-2 due to the pressure generated at this time. The working fluid moved to the heat dissipation portion 230-2 may be liquefied in the heat dissipation portion 230-2 which is relatively cold, and the liquefied working fluid F2 may be moved to the heat receiving portion 230-1 by the capillary force caused by the wick 233.

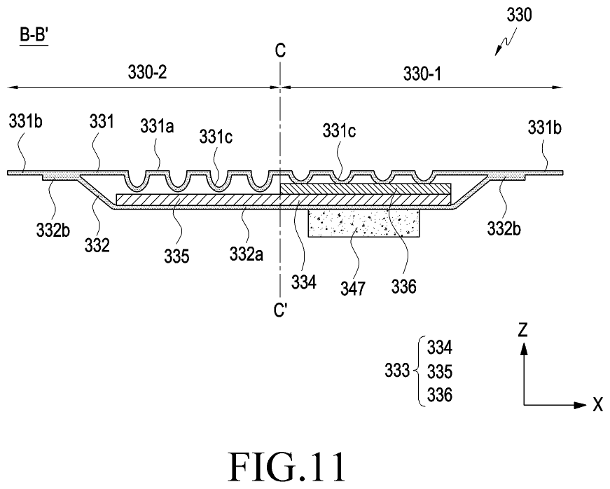

FIG. 10 is a cross-sectional view illustrating an example heat dissipation structure of an electronic device according to an embodiment of the disclosure. FIG. 11 is a cross-sectional view illustrating an example heat dissipation member of an electronic device according to an embodiment of the disclosure.

Referring to FIG. 10, an electronic device 300 according to an embodiment of the disclosure may include a housing (e.g., the housing 201 of FIG. 2), a display 310, and a printed circuit board 340. At least one component 341 (e.g., an integrated circuit chip) may be disposed on the printed circuit board 340. The electronic device 300 may include a heat dissipation structure disposed inside the housing 301, e.g., between the display 310 and the printed circuit board 340. However, the disclosure is not necessarily limited thereto, and as described above in FIG. 7, an embodiment in which the heat dissipation structure is disposed between the printed circuit board 340 and the rear plate (e.g., the rear plate 211 of FIG. 3) may also be possible. Hereinafter, for convenience of description, an embodiment in which the heat dissipation structure is disposed between the display 310 and the printed circuit board 340 is described. Hereinafter, in describing the electronic device 300 and/or the heat dissipation structure of FIG. 10, those overlapping the electronic device 200 and/or the heat dissipation sheet according to that described above with reference to FIG. 7 may be omitted from the detailed description.

The electronic device 300 and/or the heat dissipation structure may include at least a portion of the support member 320 disposed between the display 310 and the printed circuit board 340. The support member 320 (e.g., the first support member 220 of FIG. 4 or 5) may have a substantially flat plate shape, and may be at least partially disposed in a space between the first surface (or front surface) 201A of FIG. 2 or the second surface (or rear surface) 201B of FIG. 3. In an embodiment, the support member 320 may include a first surface 320a facing the display 310 and a second surface 320b facing the printed circuit board 340. According to an embodiment, the heat dissipation member 330 may be fixed on the first surface 320a of the support member 320 by a bonding member 321 such as a double-sided tape. In an embodiment, the heat dissipation member 330 may be fixed to the support member 320 by welding. At least one component 341 may be disposed on the second surface 320b of the support member 320. The at least one component 341 may be disposed on the second surface 320b of the support member 320 while being disposed on one side surface of the printed circuit board 340. The electronic device 300 and/or the heat dissipation structure may include the heat dissipation member 330 disposed on one surface (e.g., the first surface 320a of the support member 320) of the support member and including a wick. The electronic device 300 and/or the heat dissipation structure may include a thermal conductive material 343 disposed in contact with at least one component 341. The thermally conductive material 343 may include a thermal interface material (TIM). The thermally conductive material 343 may correspond to, e.g., the thermally conductive material 243 described above with reference to FIG. 7. The thermally conductive material 343 may be stacked on at least one component 341 in a space surrounded by the shield can 349 (e.g., the shield can 249 of FIG. 7). According to an embodiment, the thermally conductive material 343 may include a thermal interface material (TIM) and a thermally conductive block 347. In FIG. 10, the thermally conductive block 347 may be illustrated as being disposed between the thermally conductive material 343 formed of TIM and the heat dissipation member 330. The thermally conductive block 347 is formed of a material having high thermal conductivity such as copper, and may transfer heat between the thermal conductive material 343 and the heat dissipation member 330. According to an embodiment, according to that illustrated in FIG. 10, an opening 322 may be formed in the support member 320 at a position corresponding to the at least one component 341. The opening 322 may be formed through the shielding sheet 345 and the shield can 349. Further, according to FIG. 10, the thermal conduction block 347 may be disposed in the opening 332. In FIG. 10, instead of the support member 320, a member having higher thermal conductivity than the support member 320, e.g., the thermally conductive block 347, may be disposed to be directly stacked on the at least one component 341 and the thermally conductive material 343, thereby simplifying the stacked structure between the at least one component 341 and the heat dissipation member 330 and reducing thermal resistance. This may provide a temperature enhancing effect of reducing the high temperature formed in the at least one component 341. Referring to FIG. 11, the heat dissipation member 330 may include a first plate 331 (e.g., an upper plate) and a second plate 332 (e.g., a lower plate). When the first plate 331 and the second plate 332 are coupled to each other, a chamber through which the working fluid may flow may be formed therein. For example, the heat dissipation member 330 may include a chamber portion 331a and 332a and a flange portion 331b and 332b provided on at least a portion of an edge of the chamber portion 331a and 332a. For example, the heat dissipation member 330 may include a plurality of fillers 331c.

The electronic device 300 and/or the heat dissipation structure according to an embodiment of the disclosure may include a wick 333 and may include a first portion 334 disposed in the heat receiving portion 330-1 and a second portion 335 disposed in the heat dissipation portion 330-2. One of the first portion 334 or the second portion 335 may further include a reinforced portion (or reinforced wick portion) 336 compared to the other portion. For example, the first portion 334 of the first portion 334 or the second portion 335 may be formed to be thicker than the second portion 335. According to an embodiment, the thicker first portion 334 may further include a reinforced portion 336 and may be thicker than the second portion 335. Alternatively, the first portion 334 itself may be formed to be thicker than the second portion 335. According to an embodiment, the reinforced portion 336 may be a third portion 336 different from the first portion 334 and/or the second portion 335. For example, the third portion 336 may be a portion physically separated from the first portion 334 and/or the second portion 335. For example, when the first portion 334 and the second portion 335 are provided as substantially one wick (e.g., a first metal mesh), the third portion 336 may be provided as a wick (e.g., a second metal mesh) provided separately from the first portion 334 and the second portion 335. According to an embodiment, the third portion 336 may be a portion that is different in material from the first portion 334 and/or the second portion 335. According to an embodiment, the reinforced portion (e.g., the third portion 336) may be formed to integrally extend from the first portion 334 or the second portion 335. For example, the reinforced portion 336 may not be a portion physically separated from the first portion 334 and/or the second portion 335, but may be a portion formed substantially integrally. For example, referring to FIG. 11, the reinforced portion 336 may be stacked on the first portion 334 so that the first portion 334 is formed to be substantially thicker than the second portion 335. By including the reinforced wick 336, the electronic device 300 and/or the heat dissipation structure may increase the volume occupied by the element (wick 333) for enhancing the heat dissipation performance per unit volume of the space in which the working fluid flows in the heat dissipation member 330 at the position where the wick 333 is formed, thereby facilitating the movement of the liquid working fluid.

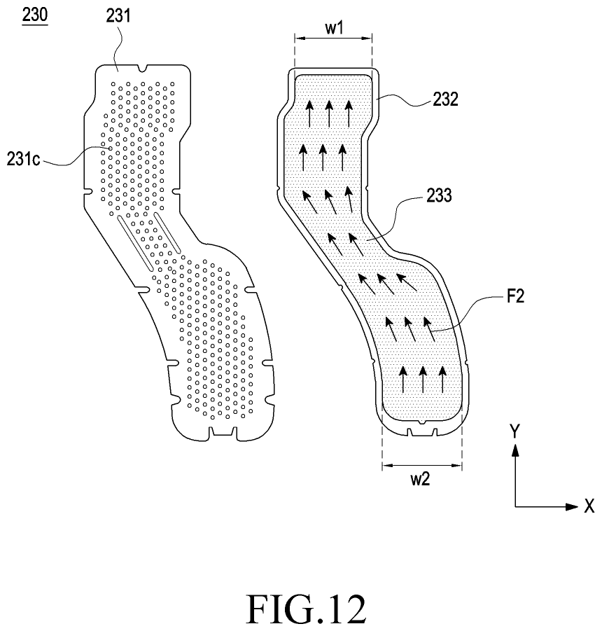

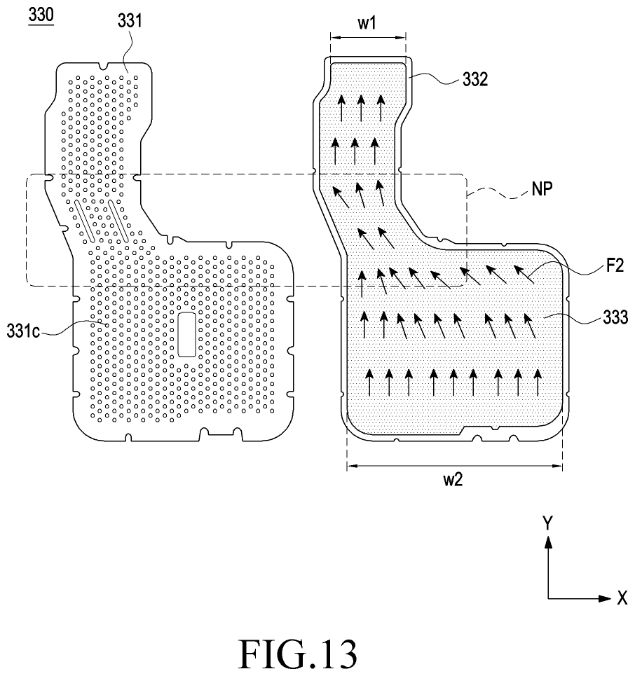

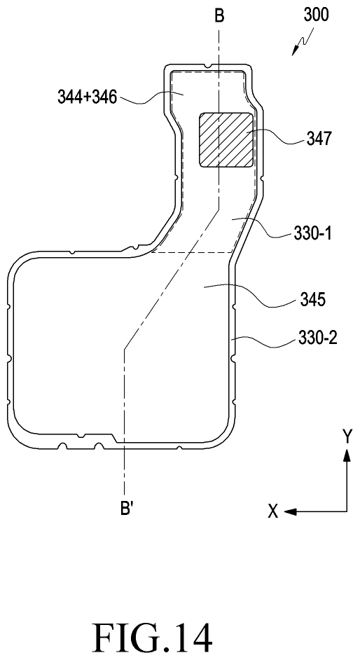

FIG. 12 is a diagram illustrating an example heat dissipation member according to an embodiment of the disclosure. FIG. 13 is a diagram illustrating an example heat dissipation member according to an embodiment of the disclosure. FIG. 14 is a diagram illustrating a state in which a thermally conductive block is disposed on a rear surface of a heat dissipation member according to an embodiment of the disclosure.

FIG. 12 is a diagram illustrating an example heat dissipation member included in the electronic device 200 and/or the heat dissipation structure illustrated in FIG. 7. FIG. 13 is a diagram illustrating an example heat dissipation member included in the electronic device 300 and/or the heat dissipation structure illustrated in FIG. 10. FIGS. 12 and 13 may illustrate a form in which the first plate and the second plate of the heat dissipation member are separated from each other. When FIGS. 12 and 13 illustrate the first plate and the second plate included in the heat dissipation member as viewed from above, FIG. 14 may illustrate the heat dissipation member of FIG. 13 as viewed from below.

In the heat dissipation member, the heat receiving portion may have a first width W1 (or a first cross-sectional area in the X-axis direction), and the heat dissipation portion may have a second width W2 (or a second cross-sectional area in the X-axis direction). For example, in the heat dissipation member 230 illustrated in FIG. 12, the first width W1 of the heat receiving portion and the second width W2 of the heat dissipation portion may be formed to be substantially the same. In this case, the working fluid (e.g., the liquefied working fluid F2) may flow in the wick 333 without blockage. In contrast, in the heat dissipation member 330 illustrated in FIG. 13, the second width W2 of the heat dissipation portion is formed to be larger than the first width W1 of the heat receiving portion, thereby increasing the heat dissipation area, and hence increasing the heat diffusion performance of the heat dissipation member. In FIG. 13, the working fluid (e.g., the liquefied working fluid F2) may not flow smoothly due to the flow resistance while passing through the bottleneck portion NP in the wick 333. For example, when the working fluid moves from the heat dissipation part side to the hydrothermal part side, high flow resistance may occur in the bottleneck NP. According to an embodiment of the disclosure, by disposing the reinforced wick 333 in a narrow portion (or a portion having a small cross-sectional area in the X-axis direction), it is possible to smoothly flow the working fluid when the heat dissipation portion and the heat receiving portion are formed to have different widths (or cross-sectional areas). For reference, FIG. 13 illustrates that the width of the heat dissipation portion corresponding to the position where the battery is disposed is wider than the width of the heat receiving portion corresponding to the position where at least one component is disposed, but the disclosure is not necessarily limited thereto. For example, the width of the heat receiving portion may be wider than the width of the heat dissipation portion and, in this case, the reinforced wick may be disposed in the heat dissipation portion.

Further, the reinforced wick may be disposed over the entire area of the heat receiving portion or the heat dissipation portion, but is not necessarily limited thereto. For example, referring to FIGS. 13 and 14, the reinforced wick may be disposed only at a position corresponding to the at least one component 341.

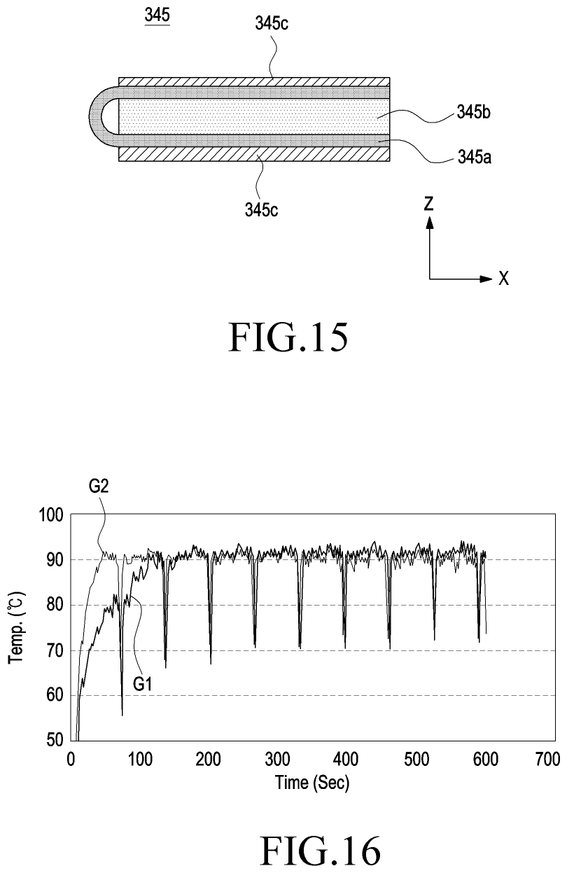

FIG. 15 is a cross-sectional view illustrating a shielding sheet according to an embodiment of the disclosure.

Referring to FIGS. 10 and 15 together, the electronic device 300 and/or the heat dissipation structure of the disclosure may further include a thermally conductive block 347 instead of the support member 320, and the thermally conductive block 347 may be disposed in at least a portion of the opening 322 formed in the support member 320. Accordingly, the shielding sheet 345 may not be formed at the position corresponding to the at least one component 341. In order to secure the shielding performance in the electronic device 300 and/or the heat dissipation structure of the disclosure, according to an embodiment of the disclosure, a conductive shielding sheet may be further included as the shielding sheet 345. For example, the electronic device 300 and/or the heat dissipation structure may include a conductive shielding sheet including a compressible foam 345b, a shielding film 345a disposed on two opposite surfaces of the compressible foam, and a conductive double-sided tape 345c, as the shielding sheet 345. Further, according to an embodiment, the conductive double-sided tape may be applied as the double-sided tape 321 disposed between the support member 320 and the heat dissipation member 330 in the electronic device 300 and/or the heat dissipation structure. By including the conductive shielding sheet 345 and the conductive double-sided tape 321, it is possible to compensate for a step between components and prevent and/or reduce leakage of noise in applying the electronic device 300 and/or the heat dissipation structure of the disclosure.

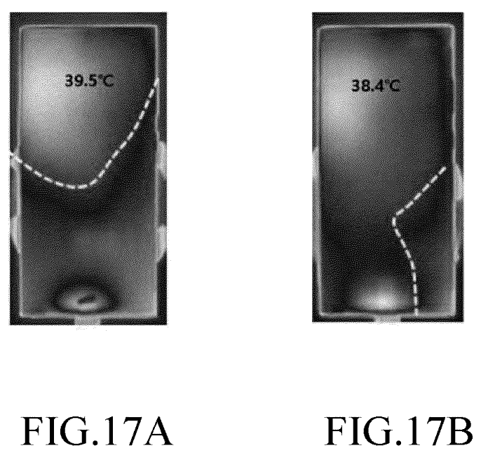

FIG. 16 is a graph illustrating a temperature enhancing effect of a heat dissipation structure according to an embodiment of the disclosure. FIGS. 17A and 17B are diagrams illustrating a temperature enhancing effect of an electronic device according to an embodiment of the disclosure.

FIG. 16 illustrates the time when the target component reaches a control temperature when the electronic device 200 and/or the heat dissipation sheet according to the embodiment of FIG. 7 is applied (G1) and the time when the target component reaches the control temperature when the electronic device 300 and/or the heat dissipation sheet according to the embodiment of FIG. 10 is applied (G2). The horizontal axis of FIG. 16 may denote the required time (sec), and the vertical axis may denote the reaching temperature (C). Referring to FIG. 16, in the case of the G2 graph, the control temperature reaching time is earlier than that of the G1 graph, so that it may be identified that the reaction rate may be further enhanced in controlling the target product. In other words, the electronic device 300 according to the embodiment of FIG. 10 may have an excellent heat dissipation effect as compared to the electronic device 200 according to the embodiment of FIG. 7.

FIG. 17A illustrates the temperature of the front surface of the electronic device when the electronic device 200 and/or heat dissipation sheet according to FIG. 7 is applied. FIG. 17B may illustrate the temperature of the front surface of the electronic device when the electronic device 300 and/or the heat dissipation sheet according to FIG. 10 is applied, and the heat dissipation member in which the width of the heat dissipation portion is larger than the width of the heat receiving portion according to FIG. 13 is applied. The electronic device 300 and/or the heat dissipation structure according to FIG. 10 may have higher heat resistance performance than that of the electronic device 200 and/or the heat dissipation structure, thus increasing heat dissipation performance for at least one component. However, as the thermal resistance is decreased, the amount of heat transferred to the front surface of the electronic device is increased, and thus the temperature of the front surface of the electronic device may further increase. By applying a heat dissipation member (e.g., a large-area heat dissipation member) in which the width of the heat dissipation portion is wider than the width of the heat receiving portion as in FIG. 13 to prevent and/or avoid the issue, it may be identified that an enhancing effect for the temperature of the front surface of the electronic device is obtained.

Effects of the disclosure are not limited to the foregoing, and other unmentioned effects would be apparent to one of ordinary skill in the art from the description of the foregoing embodiment(s).

The electronic device according to various embodiments may be one of various types of devices. The electronic devices may include, for example, a portable communication device (e.g., a smartphone), a computer device, a portable multimedia device, a portable medical device, a camera, a wearable device, a home appliance, or the like. The electronic devices according to an embodiment are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used herein, the term “module” may include a unit implemented in hardware, software, firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program) including one or more instructions that are stored in a storage medium (e.g., internal memory or external memory) that is readable by a machine (e.g., the electronic device). For example, a processor (e.g., the processor) of the machine (e.g., the electronic device) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to an example embodiment of the disclosure, an electronic device may comprise: a housing forming an exterior of the electronic device, a printed circuit board on which at least one component is disposed, and a heat dissipation member contacting the at least one component or contacting the at least one component through a thermally conductive material, the heat dissipation member including a first plate, a second plate and a wick. The wick 333 may be disposed on a second plate inside the heat dissipation member and includes a first portion and a second portion. The first portion may be thicker than the second portion.

According to an example embodiment, the electronic device may further comprise a support accommodated in the housing. The heat dissipation member may be disposed on one surface of the support.

According to an example embodiment, the thermally conductive material may include a thermal interface material (TIM) and a thermally conductive block.

According to an example embodiment, the thermally conductive block may be disposed on an opening formed in the support.

According to an example embodiment, the at least one component may contact the second plate, or contact the second plate through the thermally conductive material.

According to an example embodiment, the first portion may contact the at least one component, or contact the at least one component through the thermally conductive material, and the second portion may not contact the at least one component and may not contact the at least one component through the thermally conductive material.

According to an example embodiment, the first portion may further include a reinforced portion.

According to an example embodiment, the first portion may be disposed on a narrower one of a heat receiving portion of the heat dissipation member having a first width, and a heat dissipation portion of the heat dissipation member having a second width.

According to an example embodiment, the first portion may include a bottleneck portion in which a width of the heat dissipation member is narrowed.

According to an example embodiment, the electronic device may further comprise: a battery having at least a portion disposed on a same plane as the printed circuit board. The heat receiving portion of the heat dissipation member may be disposed at a position corresponding to the at least one component, and the heat radiating portion of the heat dissipation member may be disposed at a position corresponding to the battery.

According to an example embodiment, the electronic device may further comprise a shield can disposed on the printed circuit board to at least partially surround the at least one component, and a shielding sheet stacked on at least a portion of the shield can.

According to an example embodiment, the shielding sheet may include a conductive shielding sheet.

According to an example embodiment, the shielding sheet may include a compressible foam, a shielding film disposed on two opposite surfaces of the compressible foam, and/or a conductive double-sided tape.

According to an example embodiment, the electronic device may further comprise a conductive double-sided tape disposed between the support and the heat dissipation member.

According to an example embodiment, the heat dissipation member may include at least one of copper, stainless steel, aluminum, titanium, or magnesium.

According to an example embodiment of the disclosure, an electronic device may comprise: a housing including a first surface and a second surface facing in a direction opposite to the first surface, a support accommodated in the housing between the first surface and the second surface, a heat dissipation member comprising a chamber disposed on one surface of the support and including a wick, a printed circuit board accommodated in the housing between the first surface and the second surface, and having at least one component disposed thereon, and a thermally conductive block disposed between the at least one component and the heat dissipation member. The wick may include a first portion disposed on a heat receiving portion and a second portion disposed on a heat dissipation portion, and either the first portion or the second portion may further include a reinforced portion.

According to an example embodiment, the heat receiving portion may have a first width, and the heat dissipation portion may have a second width. The reinforced portion may be disposed on a portion having a narrower width of the first width of the heat receiving portion or the second width of the heat dissipation portion.

According to an example embodiment, the reinforced portion may include a bottleneck portion in which a width of the heat dissipation member is narrowed.

According to an example embodiment, the electronic device may further comprise: a battery having at least a portion disposed on a same plane as the printed circuit board. The heat receiving portion of the heat dissipation member may be disposed at a position corresponding to the at least one component, and the heat radiating portion of the heat dissipation member may be disposed at a position corresponding to the battery.

According to an example embodiment, the electronic device may further comprise a thermally conductive material (e.g., a thermal interface material) disposed between the at least one component and the thermally conductive block and disposed in contact with the at least one component.

According to an example embodiment, the thermally conductive block may be disposed on an opening formed in the support.

According to an example embodiment, the thermally conductive block may contact the heat dissipation member and the thermally conductive material.

According to an example embodiment, the electronic device may further comprise a shielding sheet stacked on at least a portion of the shield can.

According to an example embodiment, the shielding sheet may include a conductive shielding sheet.

According to an example embodiment, the shielding sheet may include a compressible foam, a shielding film disposed on two opposite surfaces of the compressible foam, and/or a conductive double-sided tape.

According to an example embodiment, the electronic device may further comprise a conductive double-sided tape disposed between the support and the heat dissipation member.

According to an example embodiment, the heat dissipation member may include at least one of copper, stainless steel, aluminum, titanium, or magnesium.

According to an example embodiment, the heat dissipation member may include a first plate and a second plate configured to provide a space for flowing the working fluid. The wick may be disposed adjacent to the second plate, and a filler may be formed adjacent to the first plate.

According to an example embodiment, the reinforced wick may include a third portion different from the first portion and/or the second portion.

According to an example embodiment, the reinforced wick may be formed to integrally extend from the first portion or the second portion.

According to an example embodiment of the disclosure, an electronic device may comprise: a housing including a first surface and a second surface facing in a direction opposite to the first surface, a support accommodated in the housing between the first surface and the second surface, and a heat dissipation member supported by the support, and including a heat receiving portion configured to vaporize a working fluid based on heat being absorbed from a heat source disposed in the electronic device, a heat dissipation portion configured to liquify a working fluid based on the heat being discharged, and a wick disposed on the heat receiving portion and the heat dissipation portion. The wick may include a first portion disposed on a heat receiving portion and a second portion disposed on a heat dissipation portion, and either the first portion or the second portion may further include a reinforced portion as compared with the other.

According to an example embodiment, the heat dissipation portion may have a first width, and the heat receiving portion may have a second width. The reinforced portion may be disposed on a portion having a relatively narrower width of the first width of the heat dissipation portion or the second width of the heat receiving portion.

According to an example embodiment, the electronic device may further comprise a printed circuit board accommodated in the housing between the first surface and the second surface, and having at least one component at least partially surrounded by a shield can disposed thereon, a thermally conductive material disposed in contact with the at least one component, and a thermally conductive block disposed between the thermally conductive material and the heat dissipation member.

According to an example embodiment, the electronic device may further comprise a conductive shielding sheet stacked on at least a portion of the shield can.

According to an example embodiment, the electronic device may further comprise a conductive double-sided tape disposed between the support and the heat dissipation member.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising:
a housing forming an exterior of the electronic device;
a printed circuit board on which at least one component is disposed; and
a heat dissipation member contacting the at least one component or contacting the at least one component through a thermally conductive material, and including a first plate, a second plate and a wick,
wherein the wick is disposed on the second plate inside the heat dissipation member and includes a first portion and a second portion, and wherein the first portion is thicker than the second portion.

2. The electronic device of claim 1, further comprising
a support accommodated in the housing,
wherein the heat dissipation member is disposed on one surface of the support.

3. The electronic device of claim 1,
wherein the thermally conductive material includes a thermal interface material (TIM) and a thermally conductive block.

4. The electronic device of claim 3,
wherein the thermally conductive block is disposed on an opening formed in the support.

5. The electronic device of claim 1,
wherein the at least one component contacts the second plate, or contacts the second plate through the thermally conductive material.

6. The electronic device of claim 1,
wherein the first portion contacts the at least one component, or contacts the at least one component through the thermally conductive material, and
wherein the second portion does not contact the at least one component and does not contact the at least one component through the thermally conductive material.

7. The electronic device of claim 1,
wherein the first portion includes a reinforced portion.

8. The electronic device of claim 1,
wherein the first portion is disposed on a narrower one of a heat receiving portion of the heat dissipation member having a first width, and a heat dissipation portion of the heat dissipation member having a second width.

9. The electronic device of claim 1,
wherein the first portion includes a bottleneck portion in which a width of the heat dissipation member is narrowed.

10. The electronic device of claim 1, further comprising
a battery having at least a portion disposed on a same plane as the printed circuit board, and wherein a heat receiving portion of the heat dissipation member is disposed at a position corresponding to the at least one component, and a heat radiating portion of the heat dissipation member is disposed at a position corresponding to the battery.

11. The electronic device of claim 2, further comprising:
a shield can disposed on the printed circuit board to at least partially surround the at least one component; and
a shielding sheet stacked on at least a portion of the shield can.

12. The electronic device of claim 11,
wherein the shielding sheet includes a conductive shielding sheet.

13. The electronic device of claim 11,
wherein the shielding sheet includes a compressible foam, a shielding film disposed on two opposite surfaces of the compressible foam, and/or a conductive double-sided tape.

14. The electronic device of claim 2, further comprising
a conductive double-sided tape disposed between the support and the heat dissipation member.

15. The electronic device of claim 1,
wherein the heat dissipation member comprises at least one of copper, stainless steel, aluminum, titanium, or magnesium.

16. An electronic device, comprising:
a housing including a first surface and a second surface facing in a direction opposite to the first surface;
a support accommodated in the housing between the first surface and the second surface; and
a heat dissipation member comprising a chamber supported by the support, and including a heat receiving portion configured to vaporize a working fluid based on heat being absorbed from a heat source disposed in the electronic device, a heat dissipation portion configured to liquify the working fluid based on the heat being discharged, and a wick disposed on the heat receiving portion and the heat dissipation portion,
wherein the wick includes a first portion disposed on the heat receiving portion and a second portion disposed on the heat dissipation portion, and wherein either the first portion or the second portion includes a reinforced portion.

17. The electronic device of claim 16,
wherein the heat dissipation portion has a first width, and the heat receiving portion has a second width, and
wherein the reinforced portion is disposed on a portion having a narrower width of the first width of the heat dissipation portion or the second width of the heat receiving portion.

18. The electronic device of claim 16, further comprising:
a printed circuit board accommodated in the housing between the first surface and the second surface, and having at least one component at least partially surrounded by a shield can disposed thereon;
a thermally conductive material disposed in contact with the at least one component; and
a thermally conductive block disposed between the thermally conductive material and the heat dissipation member.

19. An electronic device comprising:
a housing including a first surface and a second surface facing in a direction opposite to the first surface;
a support accommodated in the housing between the first surface and the second surface;
a heat dissipation member disposed on one surface of the support and including a wick;
a printed circuit board accommodated in the housing between the first surface and the second surface, and having at least one component disposed thereon; and
a thermally conductive block disposed between the at least one component and the heat dissipation member,
wherein the wick includes a first portion disposed on a heat receiving portion and a second portion \disposed on a heat dissipation portion, and wherein either the first portion or the second portion further includes a reinforced portion.

20. The electronic device of claim 19,
wherein the reinforced wick comprises a third portion different from the first portion and/or the second portion, or
the reinforced wick comprises a portion formed to extend integrally from the first portion or the second portion.
